(19) United States
(12) Patent Application Publication
(10) Pub. No.: US 2026/0305411 A1
(43) Pub. Date: Oct. 1, 2026

(54) SEMICONDUCTOR PACKAGE USING BONDING WIRE AS INTERCONNECTION AND METHOD OF MANUFACTURING THE SAME

(71) Applicant: Samsung Electronics Co., Ltd., Suwon-si (KR)

(72) Inventor: Peng Zhang, Suzhou Industrial Park (CN)

(21) Appl. No.: 19/183,982

(22) Filed: Apr. 21, 2025

(30) Foreign Application Priority Data
Apr. 1, 2025 (CN) 202510401804.0

(51) Int. Cl. H01L 23/00; H01L 21/56; H01L 23/31; H01L 23/498; H01L 25/00; H01L 25/065; H01L 25/18

(52) U.S. Cl. CPC H10W 70/65; H10W 74/01; H10W 74/117; H10W 90/00; H10W 46/00; H10W 90/24; H10W 90/701; H10W 90/724; H10W 90/752; H10W 90/754

(57) ABSTRACT

A semiconductor package includes: a substrate including a first surface and a second surface opposite to each other, and connection pads on the first surface of the substrate; a first chip disposed on the first surface of the substrate; a first chip stack including a plurality of second chips, the plurality of second chips sequentially stacked on the first chip with active surfaces facing downward toward the substrate; a second chip stack including a plurality of third chips, the plurality of third chips sequentially stacked on the first chip with active surfaces facing downward toward the substrate; and an encapsulation layer covering the first chip, the first chip stack and the second chip stack on the first surface of the substrate, wherein the first chip stack and the second chip stack are spaced apart from each other in a first direction parallel to the first surface of the substrate, the plurality of second chips are electrically connected to each other through first bonding wires, the plurality of third chips are electrically connected to each other through second bonding wires, and a set of lowermost first bonding wires of the first bonding wires and a set of lowermost second bonding wires of the second bonding wires are connected to the connection pads, respectively.

### CROSS-REFERENCE TO RELATED APPLICATIONS

This application claims priority to Chinese Patent Application No. 202510401804.0, filed on Apr. 1, 2025, the contents of which are incorporated herein by reference in their entirety.

### TECHNICAL FIELD

Embodiments of the present disclosure relate to the field of semiconductor packages, and particularly relate to a semiconductor package using a bonding wire as an interconnection and a method of manufacturing the same.

### BACKGROUND

Generally, in order to achieve multi-chip stacking, each chip constituting a semiconductor package is connected to a corresponding substrate using a wire bonding technique, and then exposed cells on the substrate are plastically encapsulated through a molding process to form a package.

FIG. 1 is a schematic diagram of a semiconductor package according to the related art. As illustrated in FIG. 1, a semiconductor package 1000 may include: a substrate 1, a dummy chip 2, a plurality of first chips 3, a bonding wire 4 (e.g., plurality of bonding wires), a second chip 5, an underfill 6, a bump 7 (e.g., plurality of bumps), a conductive pad 8 (e.g., plurality of pads), an external connection terminal 9 (e.g., plurality of external connection terminals) such as a pin, bump, or ball and an encapsulation layer 10. The second chip 5 is disposed on an upper surface of the substrate 1 in a flip-chip manner. The underfill 6 may surround a side surface of the bumps 7 and a portion of a side surface of the second chip 5. The substrate 1 may be a printed circuit board. The second chip 5 may be a controller chip. The dummy chip 2 may be a chip not having an electrical function, such as a piece of bulk silicon, or other semiconductor or insulative material, and two dummy chips 2 may be respectively arranged on opposite sides of the second chip 5 for supporting a stack of upper chips of different sizes. The plurality of first chips 3 (e.g., upper chips) may be memory chips. The plurality of first chips 3 may be stacked on the dummy chip 2 to form a staircase structure while exposing connection pads disposed on an active surface of each first chip 3. In this manner, an active surface of each first chip 3 may face upward, away from the substrate 1. An adhesive layer 11 may be disposed between adjacent first chips 3. The bonding wires 4 may electrically connect a connection pad of the each first chip 3 to the substrate 1 and electrically connect the plurality of first chips 3 to each other. The encapsulation layer 10 may encapsulate the aforementioned elements on the substrate 1 so as to protect them from the external environmental influences. Conductive pads 8 may be disposed on a lower surface of the substrate 1. External connection terminals 9 may be located on the conductive pads 8 to connect the semiconductor package 1000 to an external device. Internal wiring in the substrate 1 may connect pads on the top surface of the substrate 1, which connect to the bonding wires 4, to the conductive pads 8 on the bottom surface of the substrate.

The semiconductor package described above according to the related art has the following disadvantages: since a wire bonding technique is used to achieve the interconnection between elements, and a wire will occupy a space in a vertical direction and a horizontal direction, consequently, it is difficult to reduce a size of a semiconductor package. In addition, in the process of stacking chips of different functions or different sizes, a dummy chip is usually used to provide a support surface to facilitate stacking of upper chips, which also prevents miniaturization of a semiconductor package to some extent.

### SUMMARY

In order to address the above disadvantages, embodiments of the present disclosure provide a semiconductor package using a bonding wire as an interconnection and a method of manufacturing the same. In the semiconductor package according to the embodiments of the present disclosure, instead of a bump structure unit commonly used in a flip chip process, a bonding wire is used as an interconnection between elements and an electrical connection between an active surface of a semiconductor chip and a substrate is realized in a flip-chip manner, such that a thickness of the semiconductor package can be reduced and the cost can be lowered. In addition, since a dummy chip as a support is no longer needed, a chip stack structure can be simplified, and interconnection density can be improved.

According to an aspect of the embodiments of the present disclosure, a semiconductor package includes: a substrate including a first surface and a second surface opposite to each other, and connection pads on the first surface of the substrate; a first chip disposed on the first surface of the substrate; a first chip stack including a plurality of second chips, the plurality of second chips sequentially stacked on the first chip with active surfaces facing downward toward the substrate; a second chip stack including a plurality of third chips, the plurality of third chips sequentially stacked on the first chip with active surfaces facing downward toward the substrate; and an encapsulation layer covering the first chip, the first chip stack and the second chip stack on the first surface of the substrate, wherein the first chip stack and the second chip stack are spaced apart from each other in a first direction parallel to the first surface of the substrate, the plurality of second chips are electrically connected to each other through first bonding wires, the plurality of third chips are electrically connected to each other through second bonding wires, and a set of lowermost first bonding wires of the first bonding wires and a set of lowermost second bonding wires of the second bonding wires are connected to the connection pads, respectively.

Further, each of a lowermost second chip of the first chip stack and a lowermost third chip of the second chip stack may overlap the first chip in a second direction perpendicular to the first surface of the substrate.

Further, each of the first chip stack and the second chip stack may have a staircase structure.

Further, a distance between each second chip of the first chip stack and a third chip of the second chip stack located at the same level may increase along the second direction.

Further, the connection pads may include a first connection pads and second connection pads, the bonding wires of the set of lowermost first bonding wires may be respectively connected to the first connection pads, and the bonding wires of the set of lowermost second bonding wires may be respectively connected to the second connection pads.

Further, a first distance from each first connection pad to a first side surface of the first chip may be different from a second distance from each second connection pad to a second side surface of the first chip opposite to the first side surface.

Further, the first distance may be greater than the second distance.

Further, bump pads may be disposed on the first surface of the substrate, the first chip may include a passive surface in contact with the first chip stack and the second chip stack and an active surface opposite to the passive surface, bumps may be disposed on the active surface of the first chip, and the first chip may be electrically connected to the bump pads via the bumps.

Further, the bump pads may be located in a central region of the first surface of the substrate, and the connection pad may be wire pads located in an edge region of the first surface of the substrate.

Further, a solder may be disposed on an upper surface of each of the connection pads, each lowermost first bonding wire may be connected to a respective solder, and each lowermost second bonding wire may be connected to a respective solder.

Further, a non-conductive film may be disposed on the first surface of the substrate, and the non-conductive film may cover the bump and a side surface of the solder.

Further, the plurality of second chips and the plurality of third chips may be memory chips and the first chip may be a controller chip.

Further, the semiconductor package may further include: a carrier substrate disposed on the encapsulation layer and covering upper surfaces of the first chip stack and the second chip stack.

Further, the semiconductor package may further include: external connection terminals disposed on the second surface of the substrate.

According to another aspect of the embodiments of the present disclosure, a semiconductor package includes a package substrate including an external-facing surface and an internal-facing surface; external connection terminals on the external-facing surface; a plurality of connection pads at the internal-facing surface; a first chip stack of semiconductor chips including a plurality of first semiconductor chips vertically stacked on the internal-facing surface, each first semiconductor chip having an active surface facing the internal-facing surface; and first bonding wires which connect first pads at the active surface of the lowermost first semiconductor chip of the first semiconductor chips to respective first connection pads, each first bonding wire including an arc portion bonded to a respective first connection pad.

Further, the semiconductor package may include a second chip stack of semiconductor chips including a plurality of second semiconductor chips vertically stacked on the internal-facing surface, each second semiconductor chip having an active surface facing the internal-facing surface; and second bonding wires which connect second pads at the active surface of the lowermost second semiconductor chip of the second semiconductor chips to respective second connection pads of the plurality of connection, each second bonding wire including an arc portion bonded to a respective second connection pad.

Further, each first bonding wire may be additionally bonded to a respective pad on an active surface of an adjacent first semiconductor chip to the lowermost first semiconductor chip, and each second bonding wire may be additionally bonded to a respective pad on an active surface of an adjacent second semiconductor chip to the lowermost second semiconductor chip.

Further, the semiconductor package may include an intermediate semiconductor chip between the package substrate and the first chip stack and between the package substrate and the second chip stack, wherein the intermediate semiconductor chip includes an active surface facing the package substrate, and a passive surface that contacts a passive surface of the lowermost first semiconductor chip of the first chip stack and a passive surface of the lowermost second semiconductor chip of the second chip stack.

Further, each of the first chip stack and the second chip stack may be formed in a staircase shape to includes semiconductor chips connected to each other via wire bonding.

Further, solders may be disposed on a surface of the connection pads, wherein the arc portions of the first bonding wires and second bonding wires are respectively bonded to the first connection pads and the second connection pads via the solders.

According to another aspect of the embodiments of the present disclosure, a method of manufacturing a semiconductor package includes: providing a carrier substrate including a first surface and a second surface opposite to each other; sequentially stacking a plurality of second chips and a plurality of third chips, respectively, on the first surface of the carrier substrate with active surfaces facing upward to form a first chip stack and a second chip stack, wherein the first chip stack and the second chip stack are spaced apart from each other in a first direction parallel to the first surface of the carrier substrate; electrically connecting the plurality of second chips to each other through first bonding wires, and electrically connecting the plurality of third chips to each other through second bonding wires; disposing a first chip on the first chip stack and the second chip stack with an active surface facing upward; forming an encapsulation layer covering the first chip, the first chip stack and the second chip stack on the first surface of the carrier substrate, wherein the encapsulation layer exposes the active surface of the first chip, uppermost first bonding wires of the first bonding wires, and uppermost second bonding wires of the second bonding wires; disposing a substrate on the encapsulation layer, such that the uppermost first bonding wires and the uppermost second bonding wires are connected to connection pads of the substrate, respectively.

Further, the substrate may include a first surface and a second surface opposite to each other, the connection pads may be on the first surface of the substrate, and the method may further include: flipping a resulting structure, and disposing an external connection terminal on the second surface of the substrate.

Further, the disposing the first chip may include: partially overlapping the first chip with each of an uppermost second chip of the first chip stack and an uppermost third chip of the second chip stack in a second direction perpendicular to the first surface of the substrate.

Further, each of the first chip stack and the second chip stack may have a staircase structure.

Further, a distance between each second chip of the first chip stack and a third chip of the second chip stack located at the same level may increase along the second direction.

Further, the connection pads may include first connection pads and second connection pads, and the disposing the substrate on the encapsulation layer may include: connecting the uppermost first bonding wires to the first connection pads, and connecting the uppermost second bonding wires to the second connection pads.

Further, a first distance from each of the first connection pads to a first side surface of the first chip may be different from a second distance from each of the second connection pads to a second side surface of the first chip opposite to the first side surface.

Further, bumps may be disposed on the active surface of the first chip, and the forming the encapsulation layer may include: forming a thickness of the encapsulation layer to expose the bumps, a highest point of a wire arc of the uppermost first bonding wires, and a highest point of a wire arc of the uppermost second bonding wires.

Further, bump pads may be disposed in a central region of the first surface of the substrate, and the connection pads may be located in an edge region of the first surface of the substrate.

Further, a solder may be disposed on a lower surface of each connection pad, and the disposing the substrate on the encapsulation layer may include: bonding the substrate to the encapsulation layer through a panel-level thermocompression bonding process such that the bumps are connected to the bump pads and the uppermost first bonding wires and the uppermost second bonding wires are connected to the solders, respectively.

Further, a non-conductive film may be disposed on an upper surface of the substrate, and the disposing the substrate on the encapsulation layer may include: the non-conductive film covering the bumps and a side surface of the solders.

### BRIEF DESCRIPTION OF THE DRAWINGS

The above and other features and advantages of the present disclosure will become more apparent from the following detailed description for embodiments of the present disclosure, taken in conjunction with the drawings. In the drawings, the same reference signs indicate the same elements, unless noted otherwise.

FIG. 1 is a schematic diagram of a semiconductor package according to the related art.

FIG. 2 is a schematic diagram of a semiconductor package according to an embodiment of the present disclosure.

FIG. 3 is a flowchart of a method of manufacturing a semiconductor package according to an embodiment of the present disclosure.

FIGS. 4, 5, 6A, 6B and 7 are sectional views of intermediate stages of the method of manufacturing the semiconductor package according to embodiments of the present disclosure.

### DETAILED DESCRIPTION OF EXEMPLARY EMBODIMENTS

Hereinafter, various embodiments of the present disclosure will be more sufficiently described by referring to drawings illustrating some embodiments. However, the present disclosure may be implemented in many different forms, and should not be interpreted to be limited to the embodiments elaborated herein.

For easy description, spatial relevancy terms (such as “below”, “under”, “beneath”, “above”, “on”, etc.) are used herein to describe a relationship between one component and the other component as illustrated in the drawings. It should be understood that, the spatial relevancy terms also intend to include different orientations of a device in usage or operation, other than the orientations painted in the drawings. For example, if the device in the drawings is flipped, the component previously described to be “below” or “under” the other component shall be oriented as “above” the other component. Therefore, the term “under” may include two orientations of “above” and “under”.

Items described in the singular herein may be provided in plural, as can be seen, for example, in the drawings. Thus, the description of a single item that is provided in plural should be understood to be applicable to the remaining plurality of items unless context indicates otherwise.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

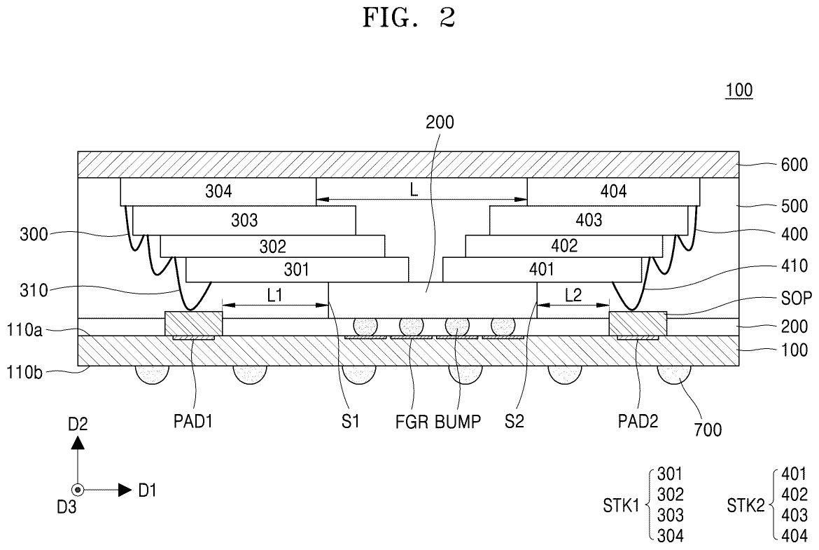

FIG. 2 is a schematic diagram of a semiconductor package according to an embodiment of the present disclosure. Referring to FIG. 2, a semiconductor package 100 includes: a substrate 110, a first chip 200, a first chip stack STK1, a second chip stack STK2 and an encapsulation layer 500.

The substrate 110 may be a package substrate that includes a first surface and a second surface opposite to each other. A plurality of connection pads (e.g., a plurality of pads PAD1 and a plurality of pads PAD2) may be on the first surface of the substrate 110. In the various embodiments, though only a single cross-section is shown in the figures, it should be noted that the substrate 110, carrier substrate 600 (described later) and various chips extend in the direction D3, and a plurality of additional pads, bumps, solders, and bonding wires are arranged in the Third direction D3. In an embodiment, the substrate 110 may be a printed circuit board. The first surface (110a) and the second surface (110b) of the substrate 110 may be an upper surface and a lower surface, respectively. However, when the substrate 110 is flipped, the first surface and the second surface of the substrate 110 may be a lower surface and an upper surface, respectively. The two surfaces of the substrate 110 may be an internal-facing, or stack-facing surface (e.g., 110a, facing the inside of the semiconductor package) and an external-facing surface (e.g., 110b, facing the outside of the semiconductor package), which terms apply regardless of the orientation of the substrate 110.

The first chip 200 may be disposed on the first surface of the substrate 110. In an embodiment, the first chip 200 may be mounted on the first surface of the substrate 110 in a flip-chip manner, e.g., so that an active surface of the first chip 200 faces the substrate. As described herein, an active surface of a chip is a surface at which active circuit components, such as transistors, are formed. In the flip-chip orientation of the first chip 200 shown in FIG. 2, the first chip 200 is electrically connected to a wiring layer in the substrate 110 via a bump interconnection, which may be a solder bump or a pillar for example. The first chip 200 may be a semiconductor chip formed on a die from a wafer and having an integrated circuit formed thereon. The first chip 200 may be an intermediate chip, between the substrate 110 and each chip stack STK1 and STK2.

The first chip stack STK1 may include a plurality of second chips 301, 302, 303 and 304 sequentially stacked on the first chip 200 with active surfaces facing downward. Each second chip 301, 302, 303, and 304 may be a semiconductor chip formed on a die from a wafer and having an integrated circuit formed thereon. The second chip stack STK2 may include a plurality of third chips 401, 402, 403 and 404 sequentially stacked on the first chip 200 with active surfaces facing downward. Each third chip 401, 402, 403, and 404 may be a semiconductor chip formed on a die from a wafer and having an integrated circuit formed thereon. In one embodiment, the plurality of second chips 301, 302, 303 and 304 and the plurality of third chips 401, 402, 403 and 404 are memory chips, for example, NAND flash memory chips. The first chip 200 may be a controller chip, for example, a processor chip.

In some embodiments, sizes and functions of the plurality of second chips 301, 302, 303 and 304 may be the same as those of the plurality of third chips 401, 402, 403 and 404. In another embodiment, sizes and functions of the plurality of second chips 301, 302, 303 and 304 may be different from those of the plurality of third chips 401, 402, 403 and 404. Although FIG. 2 shows that the first chip stack STK1 includes four second chips and the second chip stack STK2 includes four third chips, the embodiments are not limited hereto, and each chip stack may include five or more chips or less than four chips.

The encapsulation layer 500 may cover the first chip 200, the first chip stack STK1 and the second chip stack STK2 on the first surface of the substrate 110. The first chip stack STK1 and the second chip stack STK2 may be spaced apart from each other in a first direction D1. The first direction D1 may be parallel to the first surface of the substrate 110. The plurality of second chips 301, 302, 303 and 304 may be electrically connected to each other through first bonding wires 300. The plurality of third chips 401, 402, 403 and 404 may be electrically connected to each other through second bonding wires 400. The first bonding wires 300 and second bonding wires 400 that connect between two chips within each stack may be inter-chip bonding wires, which connect between chips of a stack of chips.

In some embodiments, the encapsulation layer 500 may be formed of a material such as an epoxy mold compound (EMC). Adjacent chips included in each of the first chip stack STK1 and the second chip stack STK2 may be bonded to each other via an adhesive layer or a die attachment film (DAF). As an interconnection between elements, the first bonding wires 300 and the second bonding wires 400 may each be or include a conductive material (e.g., electrically conductive material) such as a metal and may be a metal wire.

A set of lowermost first bonding wires 310 of the first bonding wires 300 and a set of lowermost second bonding wires 410 of the second bonding wires 400 may be connected to (e.g., bonded to) connection pads PAD, respectively on the upper surface of the substrate 110. The lowermost first bonding wires 310 and lowermost second bonding wires 410 may be substrate-to-chip or substrate-to-stack bonding wires (e.g., package substrate-to-chip or package substrate-to-stack bonding wires), which connect the substrate 110 to at least one chip of the stack of chips. In some embodiments, each of the lowermost first bonding wires 310 and lowermost second bonding wires 410 are inter-chip bonding wires and substrate-to-chip bonding wires, since each lowermost bonding wire may both connect a lowermost chip to a next higher chip and connect the lowermost chip to the substrate 110. According to embodiments of the present disclosure, in the semiconductor package 100, a flip-chip connection between the active surfaces of the second chips and the third chips and the substrate 110 may be performed using the first bonding wires 310 and the second bonding wires 410, which pass through the encapsulation layer 500. Because the bonding wires connect to a bottom surface of the stacked semiconductor chips rather than the top surface as is typical, the bonding can be described as upside-down wire bonding, where wires are bonded to a bottom, active surface of semiconductor chips as well as a top surface of the package substrate. As a result, a bump structure unit commonly used in a conventional flip-chip process may be replaced. Since a space inside the semiconductor package is more efficiently utilized, a thickness of the semiconductor package can be reduced. In addition, since there is no need to use a dummy chip as a support, an electrical interconnection path can be shortened, the reliability of a device can be improved, and the cost can be reduced.

Hereinafter, specific structural features of the semiconductor package 100 according to an embodiment of the present disclosure will be described in details with reference to FIG. 2.

In some embodiments, each of a lowermost second chip 301 of the first chip stack STK1 and a lowermost third chip 401 of the second chip stack STK2 may be partially superimposed on the first chip 200 in a second direction D2. For example, each of a lowermost second chip 301 of the first chip stack STK1 and a lowermost third chip 401 of the second chip stack STK2 may vertically overlap the first chip 200. For example in some embodiments, half or less than half of the lowermost second chip 301 and half or less than half of the lowermost third chip 401 overlaps and covers the first chip 200. The second direction D2 may be perpendicular to the first surface of the substrate 110 and perpendicular to the first direction D1. The second direction D2 may be a vertical direction, while the first direction D1 is a horizontal direction. Specifically, in some embodiments, a portion or all of the right half of the lowermost second chip 301 and a portion or all of the left half of the lowermost third chip 401 may be in contact with an upper surface of the first chip 200, respectively. The lowermost second chip 301 and the lowermost third chip 401 may be spaced apart from each other in the first direction D1. A left portion of the lowermost second chip 301 and a right portion of the lowermost third chip 401 may overhang beyond side surfaces and edges of the second chip 200, respectively. In this case, the first bonding wires 310 and the second bonding wires 410 may be located between the left portion of the second chip 301 and the connection pads PAD and between the right portion of the third chip 401 and the connection pads PAD, respectively. The first bonding wires 310 and second bonding wires 410 may be curved wires, or arc-shaped wires, separated from the second chip 200 with encapsulation material from the encapsulation layer 500 formed therebetween.

In some embodiments, each of the first chip stack STK1 and the second chip stack STK2 may have a staircase structure. Specifically, an inclination direction of the staircase structure of the first chip stack STK1 may be opposite to that of the staircase structure of the second chip stack STK2. In some embodiments, a distance L, in the first direction D1, between each second chip of the first chip stack STK1 and a third chip of the second chip stack STK2 located at the same level (e.g., same vertical distance above a top surface of the substrate) may increase along the second direction D2, away from the first chip 200.

In some embodiments, the connection pads of the substrate 110 may include first connection pads PAD1 and second connection pads PAD2. The lowermost first bonding wires 310 may be connected to the first connection pads PAD1 (e.g., to be bonded to and/or directly connected to the first connection pads PAD1), and the lowermost second bonding wires 410 may be connected to the second connection pads PAD2 (e.g., to be bonded to and/or directly connected to the second connection pads PAD1). The first connection pads PAD1 and the second connection pads PAD2 may be electrically connected to different external connection terminals via a wiring layer in the substrate 110, thereby transmitting or receiving different electrical signals.

In some embodiments, a first distance L1 from each first connection pad PAD1 to a first side surface S1 of the first chip 200 may be different from a second distance L2 from each second connection pad PAD2 to a second side surface S2 of the first chip 200 opposite to the first side surface S1. For example, the first distance L1 may be greater than the second distance L2 depending on the difference in size (e.g., width) of the second chip and the third chip. However, the embodiments of the present disclosure are not limited hereto, and the first distance L1 may also be equal to or less than the second distance L2.

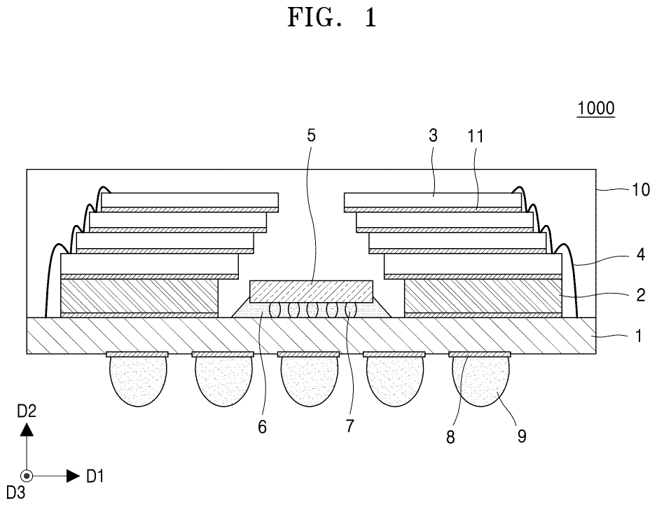

In some embodiments, a finger FGR (e.g., plurality of fingers, which may be pads such as bump pads) may be disposed on the first surface of the substrate 110. As illustrated in FIG. 1, the fingers FGR may be located in a central region of the first surface of the substrate 110. The connection pad PAD (e.g., plurality of connection pads, which may be wire pads) may be located in an edge region of the first surface of the substrate 110. Both the bump pads and the wire pads may have the same structure, and may be for example, formed of a metal such as copper, aluminum, gold, nickel and/or palladium at a surface of the substrate 110 and have a flat surface facing the same direction as the internal-facing surface 110a of the substrate 110. The edge regions of the first surface of the substrate 110 may be disposed around the central region. When viewed from the third direction D3, the edge regions may each include at least one third of the substrate 110 at one side of the substrate, and the central region in one embodiment may include a middle third of the substrate 110. The fingers FGR may be disposed between the first connection pads PAD1 and the second connection pads PAD2 in the first direction D1.

In some embodiments, the first chip 200 may include a passive surface in contact with the first chip stack STK1 and the second chip stack STK2 and an active surface opposite to the passive surface. The passive surface of the first chip 200 may be an upper surface and the active surface may be a lower surface. Bumps BUMP may be disposed on the active surface of the first chip 200. The first chip 200 may be electrically connected to the fingers FGR of the substrate 110 via bumps BUMP. The bumps BUMP may be, for example, solder bumps, formed of a solder material.

In some embodiments, a solder SOP may be disposed on an upper surface of each connection pad PAD. In this case, the lowermost first bonding wires 310 and the lowermost second bonding wires 410 may be connected to the solder SOP, respectively so as to be electrically connected to, and bonded to, the connection pads PAD. An external signal may be transmitted to the second chips 301, 302, 303 and 304 and the third chips 401, 402, 403 and 404 via the solders SOP and the connection pads PAD.

In some embodiments, a non-conductive film 120 may be disposed on the first surface of the substrate 110, and the non-conductive film 120 may cover the bumps BUMP and side surfaces of the solders SOP.

In some embodiments, the semiconductor package 100 may further include a carrier substrate 600. The carrier substrate 600 may be disposed on the encapsulation layer 500 and cover upper surfaces of the first chip stack STK1 and the second chip stack STK2. The carrier substrate 600 may contact the upper surfaces of the topmost chips of the first chip stack STK1 and the second chip stack STK2 as well as an upper surface of the encapsulation layer 500. In some embodiments, the carrier substrate 600 is removed so that the upper surfaces of the topmost chips of the first chip stack STK1 and the second chip stack STK2 as well as an upper surface of the encapsulation layer 500 form a top surface of the semiconductor package 100.

As depicted in the embodiment of FIG. 2, the semiconductor package 100 further includes external connection terminals 700. The external connection terminals 700 may be disposed on the second surface of the substrate 110, and may be bumps or balls such as solder bumps or solder balls. The semiconductor package 100 may communicate with an external device via the external connection terminals 700.

It should be noted that while a plan view is not shown, the sizes of the different semiconductor chips and the substrate 110 in a second horizontal direction perpendicular to the first direction D1 (e.g., a third direction D3) may have various relationships to each other. For example, in some embodiments, all of the second chips 301-304 may have the same length in the third direction D3 and may have their edges aligned with each other in the Third direction D3. Similarly, all of the third chips 401-404 may have the same length in the Third direction D3 and may have their edges aligned with each other in the Third direction D3. In some embodiments, all of the second chips 301-304 and third chips 401-404 may have the same width in the Third direction D3. In addition, the first chip 200 in some embodiments may have a greater length in the Third direction D3 than the second chips 301-304 and third chips 401-404, or in some embodiments, may have the same or a smaller width than the second chips 301-304 and third chips 401-404.

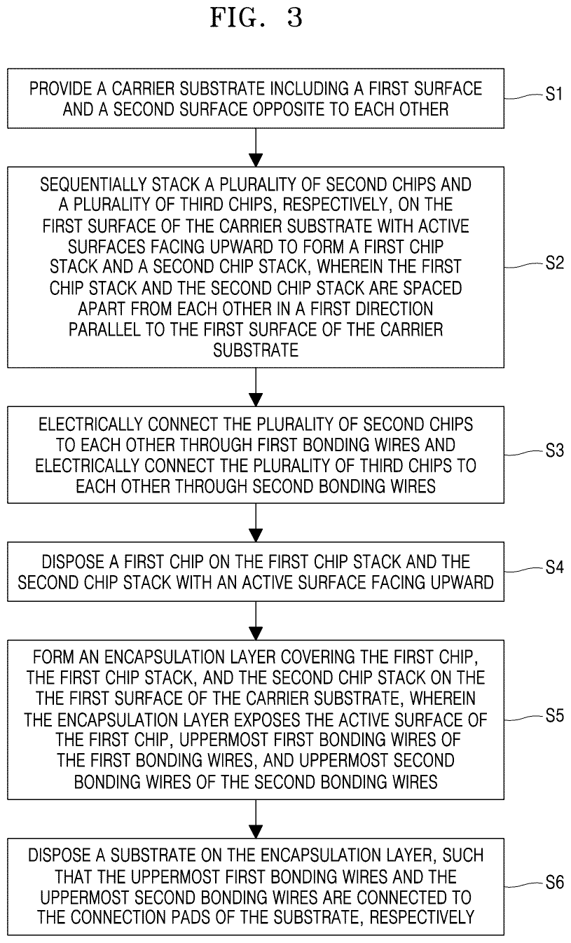

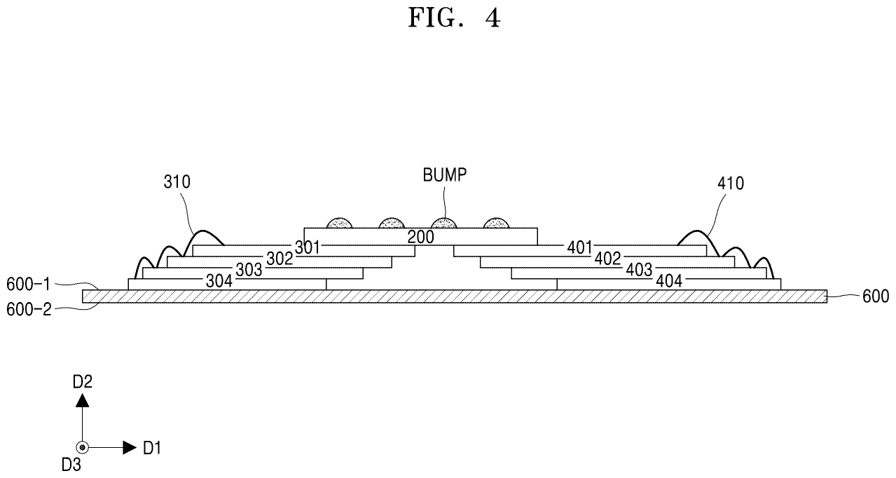

Hereinafter, a method of manufacturing a semiconductor package according to embodiments of the present disclosure will be described in detail with reference to FIGS. 3-7. FIG. 3 is a flowchart of a method of manufacturing a semiconductor package according to an embodiment of the present disclosure. FIGS. 4, 5, 6A, 6B, and 7 are sectional views of intermediate stages of the method of manufacturing the semiconductor package according to embodiments of the present disclosure. Hereinafter, the semiconductor package according to the embodiments of the present disclosure may be the semiconductor package 100 shown in FIG. 2.

Referring to FIGS. 3 and 4, a method of manufacturing the semiconductor package according to one embodiment includes: in step S1, providing a carrier substrate 600. The carrier substrate 600 includes a first surface and a second surface opposite to each other. The first surface and the second surface of the carrier substrate 600 may be an upper surface and a lower surface, respectively. However, when the carrier substrate 600 is flipped in the subsequent process, the first surface and the second surface of the carrier substrate 600 may be a lower surface and an upper surface, respectively. Once step S2 begins and through completion of the package, the carrier substrate may be described as having an internal-facing surface 600-1 (facing other components of the package) and an external-facing surface 600-2 (facing the outside of the package). The carrier substrate 600 may be formed of, for example, an insulating material such as resin. In other embodiments, the carrier substrate 600 may be formed of, for example, glass, silicon (Si), polymer, metal and/or ceramic.

In step S2, a plurality of second chips 301, 302, 303 and 304 and a plurality of third chips 401, 402, 403 and 404 are sequentially stacked on the first surface of the carrier substrate 600, respectively with active surfaces facing upward to form a first chip stack STK1 and a second chip stack STK2. The first chip stack STK1 and the second chip stack STK2 may be spaced apart from each other in a first direction D1 parallel to the first surface of the carrier substrate 600. In this manner, the active surfaces face the same direction as the internal-facing surface 600-1 of the carrier substrate 600.

In step S3, the plurality of second chips 301, 302, 303 and 304 are electrically connected to each other through first bonding wires 300, which may be inter-chip bonding wires, and the plurality of third chips 401, 402, 403 and 404 are electrically connected to each other through second bonding wires 400, which may be inter-chip bonding wires. The step S3 may be performed through a wire bonding process of bonding respective wires to respective chip pads on the active surface of the chips. Each of the first bonding wires 300 and the second bonding wires 400 may be a gold (Au) wire, for example, silver, copper, aluminum and/or palladium-plated copper.

In step S4, a first chip 200 is disposed on the first chip stack STK1 and the second chip stack STK2 with an active surface facing upward.

In some embodiments, the step S4 of disposing the first chip may include: stacking the first chip on the uppermost second chip 301 of the first chip stack STK1 (e.g., the second chip furthest from the carrier substrate 600) and the uppermost third chip 401 of the second chip stack STK2 (e.g., the third chip furthest from the carrier substrate 600) such that each of the second chip 301 and the third chip 401 is partially superimposed on the first chip 200 in a second direction D2 (e.g., to vertically overlap in the second direction D2). For example, a lower surface (a passive surface) of the first chip 200 may contact a right side of an upper surface of the second chip 301 (e.g., on the right half of the chip 301) and contact a left side of an upper surface of the third chip 401 (e.g., on the left half of the chip 401). The second chip 301 and the third chip 401 may be spaced apart from each other in a first direction D1 under the first chip 200.

In some embodiments, each of the first chip stack STK1 and the second chip stack STK2 may have a staircase structure. Specifically, an inclination direction of the staircase structure of the first chip stack STK1 may be opposite to that of the staircase structure of the second chip stack STK2. More specifically, a distance L, in the first direction D1, between each second chip of the first chip stack STK1 and a third chip of the second chip stack STK2 located at the same level may increase along the second direction D2, or increase away from the first chip 200.

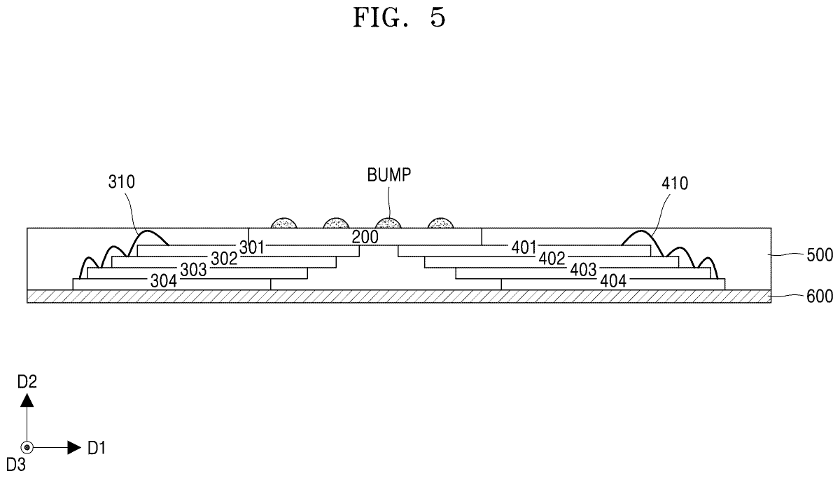

Referring to FIGS. 3 and 5, in step S5, an encapsulation layer 500 covering the first chip 200, the first chip stack STK1 and the second chip stack STK2 is formed on the first surface of the carrier substrate 600. The encapsulation layer 500 may expose the active surface of the first chip 200, the uppermost first bonding wires 310 (e.g., a set of uppermost first bonding wires 310, which may be the later-connected substrate-to-chip bonding wires) of the first bonding wires 300, and the uppermost second bonding wires 410 (e.g., a set of uppermost second bonding wires 410, which may be the later-connected substrate-to-chip bonding wires) of the second bonding wires 400.

In some embodiments, bumps BUMP may be disposed on the active surface of the first chip 200. In this case, the step S5 of forming the encapsulation layer may include: forming a thickness of the encapsulation layer 500 to expose the bumps BUMP, a highest point of a wire arc of the uppermost first bonding wires 301, and a highest point of a wire arc of the uppermost second bonding wires 410.

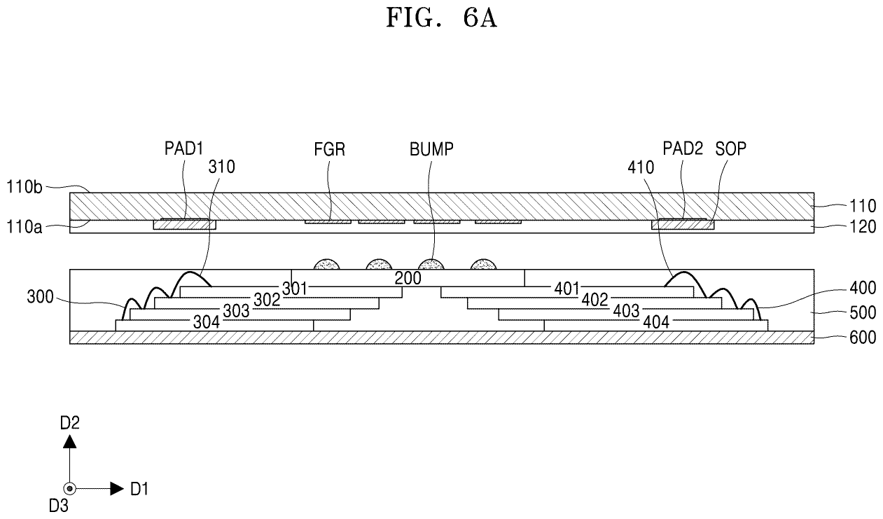

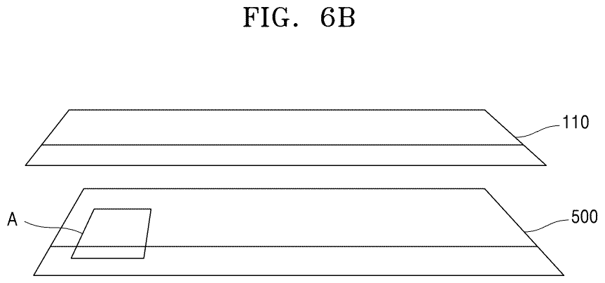

Referring to FIGS. 3 and 6A, in step S6, a substrate 110 is disposed on the encapsulation layer 500, such that the upper first bonding wires 310 and the uppermost second bonding wires 410 (e.g., an arc portion of each of these wires) are connected to the connection pads (PAD1 and PAD2) of the substrate 110, respectively. At the same time, the bumps BUMP may be connected to the fingers FGR.

The substrate 100 may include a first surface and a second surface opposite to each other. As illustrated in FIG. 6A, the first surface and the second surface of the substrate 110 may be a lower surface 110a and an upper surface 110b, respectively, which may be an internal-facing surface and an external-facing surface respectively. When the substrate 110 is flipped, the first surface and the second surface of the substrate 110 may be an upper surface and a lower surface, respectively. Connection pads PAD may be on the first surface (e.g., internal-facing surface) of the substrate 110.

In some embodiments, the connection pads PAD of the substrate 110 may include first connection pads PAD1 and a second connection pads PAD2. In this case, the step S6 of disposing the substrate on the encapsulation layer may include: connecting the uppermost first bonding wires 310 to the first connection pads PAD1, and connecting the uppermost second bonding wires 410 to the second connection pads PAD2.

Referring back to FIG. 2, in one embodiment, a first distance L1 from the first connection pad PAD1 to a first side surface S1 of the first chip 200 may be different from a second distance L2 from the second connection pad PAD2 to a second side surface S2 of the first chip 200 opposite to the first side surface S1. Specifically, the first distance L1 may be greater than the second distance L2 depending on the difference in size (e.g., width) of the second chips and the third chips. In this case, the first connection pads PAD1 may have a large wiring margin, or the number of the first connection pads PAD1 may be greater than the number of the second connection pads PAD2.

In some embodiments, fingers FGR (e.g., bump pads) may be disposed in a central region of the first surface of the substrate 110 and the connection pads PAD (e.g., wire pads) may be located in an edge region of the first surface of the substrate 110. The fingers FGR and connection pads PAD may be a wiring layer of the substrate 110, and in some embodiments may be formed in a single process.

In some embodiments, a solder SOP (e.g., solder material such as tin, lead, copper, bismuth and/or silver) may be disposed on a lower surface of the connection pad PAD. In this case, the step S6 of disposing the substrate on the encapsulation layer may include: bonding the substrate 110 to the encapsulation layer 500 through a panel-level thermocompression bonding process.

Referring to FIGS. 3, 6A and 6B, firstly, the substrate 110 may be flipped with the first surface thereof facing downward and facing the resulting structure in steps S1 to S5. Secondly, the substrate 110 may be bonded to the encapsulation layer 500 on which the bumps BUMP, the uppermost first bonding wires 310, and the uppermost second bonding wires 410 are exposed to an upper surface thereof by using a panel-level thermocompression bonding process, such that the bumps BUMP are connected to the fingers FGR and the first bonding wires 310 and the second bonding wires 410 are connected to the solders SOP, respectively, thereby completing the interconnection of the first chip, the second chips, and the third chips with the substrate 110. In this process, the arc portion of the bonding wires are bonded to bump pads (e.g., connection pads PAD) of the substrate 110 through solders SOP.

In one embodiment, a non-conductive film 120 may be disposed on the upper surface of the substrate 110. In this case, the step S6 of disposing the substrate on the encapsulation layer may further include: covering the bumps BUMP and a side surface of the solders SOP using the non-conductive film 120. The non-conductive film 120 may be, for example, thermosetting resin (epoxy resin, polyimide, acrylic resin, etc.) and/or fillers (silica, alumina, inorganic fillers).

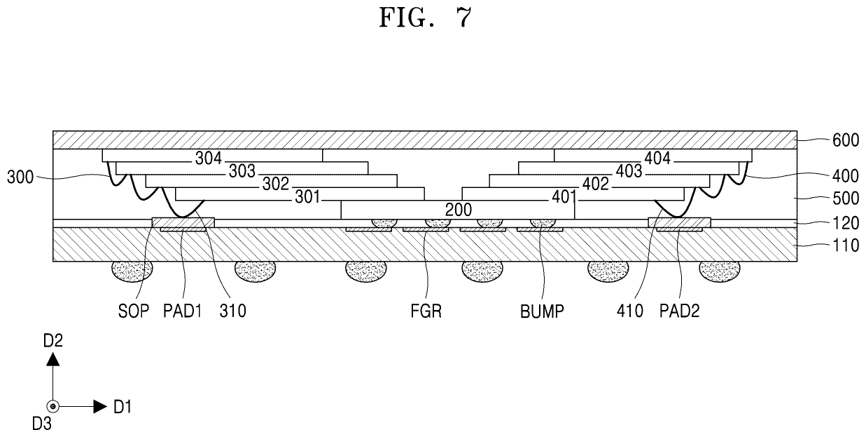

Referring to FIG. 7, in the present embodiment, the method of manufacturing the semiconductor package further includes: flipping the resulting structure in the step S6, and disposing external connection terminals 700 on the second surface of the substrate 110. Thereafter, a dicing process may also be performed to obtain the final semiconductor package 100. For example, a plurality of packages 100 may be formed together in this manner, prior to dicing.

As a summary and review, the embodiments of the present disclosure provide a semiconductor package using a bonding wire as an interconnection and a method of manufacturing the same. Instead of a bump structure unit commonly used in the flip-chip process, a bonding wire is used as an interconnection between elements, also for a flip-chip configuration. Since an expensive bump forming process is no longer performed, the production cost can be reduced. In addition, since an electrical connection between an active surface of a semiconductor chip and a substrate is still realized in a flip-chip manner, a thickness of a semiconductor package can be reduced. In addition, since a dummy chip as a support is no longer needed, a chip stack structure can be simplified, and interconnection density can be improved.

Although the embodiments of the present disclosure have been illustrated and described here, it will be understood by those skilled in the art that various modifications and changes may be made therein without departing from the spirit and scope of the present claims.

What is claimed is:

1. A semiconductor package, comprising:
a substrate comprising a first surface and a second surface opposite to each other, and connection pads on the first surface of the substrate;
a first chip disposed on the first surface of the substrate;
a first chip stack comprising a plurality of second chips, the plurality of second chips sequentially stacked on the first chip with active surfaces facing downward toward the substrate;
a second chip stack comprising a plurality of third chips, the plurality of third chips sequentially stacked on the first chip with active surfaces facing downward toward the substrate; and
an encapsulation layer covering the first chip, the first chip stack and the second chip stack on the first surface of the substrate,
wherein the first chip stack and the second chip stack are spaced apart from each other in a first direction parallel to the first surface of the substrate,
wherein the plurality of second chips are electrically connected to each other through first bonding wires, and the plurality of third chips are electrically connected to each other through second bonding wires, and
a set of lowermost first bonding wires of the first bonding wires and a set of lowermost second bonding wires of the second bonding wires are connected to the connection pads, respectively.

2. The semiconductor package of claim 1, wherein each of a lowermost second chip of the first chip stack and a lowermost third chip of the second chip stack overlaps the first chip in a second direction perpendicular to the first surface of the substrate.

3. The semiconductor package of claim 2, wherein each of the first chip stack and the second chip stack has a staircase structure.

4. The semiconductor package of claim 3, wherein a distance between each second chip of the first chip stack and a third chip of the second chip stack located at the same level increases along the second direction.

5. The semiconductor package of claim 1, wherein:
the connection pads comprises first connection pads and second connection pads,
the bonding wires of the set of lowermost first bonding wires are respectively connected to the first connection pads, and the bonding wires of the set of lowermost second bonding wires are respectively connected to the second connection pads.

6. The semiconductor package of claim 5, wherein a first distance from each first connection pad to a first side surface of the first chip is different from a second distance from each second connection pad to a second side surface of the first chip opposite to the first side surface.

7. The semiconductor package of claim 6, wherein the first distance is greater than the second distance.

8. The semiconductor package of claim 1, wherein:
bump pads are provided on the first surface of the substrate,
the first chip comprises a passive surface in contact with the first chip stack and the second chip stack and an active surface opposite to the passive surface, and
bumps are disposed on the active surface of the first chip, the first chip being electrically connected to the bump pads via the bumps.

9. The semiconductor package of claim 8, wherein
the bump pads are located in a central region of the first surface of the substrate, and
the connection pads are wire pads located in an edge region of the first surface of the substrate.

10. The semiconductor package of claim 8, wherein a solder is disposed on an upper surface of each of the connection pads, each lowermost first bonding wire is connected to a respective solder, and each lowermost second bonding wire is connected to a respective solder.

11. The semiconductor package of claim 10, wherein:
a non-conductive film is disposed on the first surface of the substrate, and
the non-conductive film covers the bumps and a side surface of the solders.

12. The semiconductor package of claim 1, wherein the plurality of second chips and the plurality of third chips are memory chips, and the first chip is a controller chip.

13. The semiconductor package of claim 1, further comprising:
a carrier substrate disposed on the encapsulation layer and covering upper surfaces of the first chip stack and the second chip stack.

14. The semiconductor package of claim 1, further comprising:
external connection terminals disposed on the second surface of the substrate.

15. A semiconductor package comprising:
a package substrate including an external-facing surface and an internal-facing surface;
external connection terminals on the external-facing surface;
a plurality of connection pads at the internal-facing surface;
a first chip stack of semiconductor chips including a plurality of first semiconductor chips vertically stacked on the internal-facing surface, each first semiconductor chip having an active surface facing the internal-facing surface; and
first bonding wires which connect first pads at the active surface of the lowermost first semiconductor chip of the first semiconductor chips to respective first connection pads of the plurality of connection pads, each first bonding wire including an arc portion bonded to a respective first connection pad.

16. The semiconductor package of claim 15, further comprising:
a second chip stack of semiconductor chips including a plurality of second semiconductor chips vertically stacked on the internal-facing surface, each second semiconductor chip having an active surface facing the internal-facing surface; and
second bonding wires which connect second pads at the active surface of the lowermost second semiconductor chip of the second semiconductor chips to respective second connection pads of the plurality of connection pads, each second bonding wire including an arc portion bonded to a respective second connection pad.

17. The semiconductor package of claim 16, wherein each first bonding wire is additionally bonded to a respective pad on an active surface of an adjacent first semiconductor chip to the lowermost first semiconductor chip, and each second bonding wire is additionally bonded to a respective pad on an active surface of an adjacent second semiconductor chip to the lowermost second semiconductor chip.

18. The semiconductor package of claim 16, further comprising:
an intermediate semiconductor chip between the package substrate and the first chip stack and between the package substrate and the second chip stack,
wherein the intermediate semiconductor chip includes an active surface facing the package substrate, and a passive surface that contacts a passive surface of the lowermost first semiconductor chip of the first chip stack and a passive surface of the lowermost second semiconductor chip of the second chip stack.

19. The semiconductor package of claim 18, wherein each of the first chip stack and the second chip stack is formed in a staircase shape to include semiconductor chips connected to each other via wire bonding.

20. The semiconductor package of claim 16, further comprising solders disposed on a surface of the connection pads, wherein the arc portions of the first bonding wires and second bonding wires are respectively bonded to the first connection pads and the second connection pads via the solders.
